(19) United States
(12) Patent Application Publication
(10) Pub. No.: US 2021/0062330 A1
(43) Pub. Date: Mar. 4, 2021

(54) SELECTIVE COBALT DEPOSITION ON COPPER SURFACES

(71) Applicant: APPLIED MATERIALS, INC., Santa Clara, CA (US)

(72) Inventors: Wenjing XU, San Jose, CA (US); Yufei HU, Fremont, CA (US); Gang SHEN, San Jose, CA (US); Feng CHEN, SAN JOSE, CA (US)

(21) Appl. No.: 17/002,296

(22) Filed: Aug. 25, 2020

Related U.S. Application Data
(60) Provisional application No. 62/894,194, filed on Aug. 30, 2019.

(51) Int. Cl. C23C 16/06; C23C 16/52; C23C 16/455

(52) U.S. Cl. CPC C23C 16/06; C23C 16/45502; C23C 16/52

(57) ABSTRACT

A method for capping a copper surface on a substrate. In embodiments, the methods include exposing a substrate including a copper surface and a dielectric surface to a cobalt precursor gas and a process gas including a reducing agent to selectively form a first cobalt capping layer over the copper surface while leaving exposed the dielectric surface during a vapor deposition process, wherein a flow rate ratio of process gas to cobalt precursor gas is at least 300:1.

### CROSS-REFERENCE TO RELATED APPLICATIONS

This application claims benefit of U.S. provisional patent application Ser. No. 62/894,194, filed Aug. 30, 2019, which is hereby incorporated herein by reference in its entirety.

### FIELD

Embodiments of the present disclosure generally relate to methods of selectively depositing a cobalt layer on a substrate.

### BACKGROUND

In semiconductor manufacturing and the formation of metal interconnects, for example copper interconnects, depositing a cobalt capping layer between the copper interconnect and the subsequently formed dielectric barrier layer improves the adhesion between the metal and the dielectric and the reliability of the interface between the copper and the dielectric portions. However, the inventors have observed that typical cobalt deposition processes such as plasma deposition processes utilizing precursors results in damage to surrounding dielectric materials, such as dielectric materials having a low dielectric constant. Further, increasing the thickness and/or deposition rate of a cobalt capping layer deposited atop a copper-filled feature may be desirable, however low selectivity during cobalt deposition problematically deposits copper atop an adjacent dielectric field resulting in shorts, leakage, poor adhesion, and/or yield loss.

Accordingly, the inventors have developed improved techniques to selectively deposit a cobalt layer on a copper surface of a substrate.

### SUMMARY

Methods for selectively depositing a cobalt layer are provided herein. In some embodiments, a method for capping a copper surface on a substrate, includes: exposing a substrate including a copper surface and a dielectric surface to a cobalt precursor gas and a process gas including a reducing agent to selectively form a first cobalt capping layer over the copper surface while leaving exposed the dielectric surface during a vapor deposition process, wherein a flow rate ratio of process gas to cobalt precursor gas is at least 300:1.

In some embodiments, a method for capping a copper surface on a substrate, includes: positioning a substrate within a processing chamber, wherein the substrate includes a copper surface and a dielectric surface; and exposing the copper surface to a cobalt precursor gas and a process gas including a reducing agent to selectively form a first cobalt capping layer over the copper surface while leaving exposed the dielectric surface during a vapor deposition process, wherein a flow rate of the cobalt precursor gas is about 10 to about 30 sccm and a flow rate of the process gas includes hydrogen flowed into a process chamber at a rate of at least 8000 sccm.

In some embodiments, the present disclosure relates to a non-transitory computer readable medium having instructions stored thereon that, when executed, cause a reaction chamber to perform a method of capping a copper surface on a substrate, including: exposing a substrate including a copper surface and a dielectric surface to a cobalt precursor gas and a process gas including a reducing agent to selectively form a first cobalt capping layer over the copper surface while leaving exposed the dielectric surface during a vapor deposition process, wherein a flow rate ratio of process gas to cobalt precursor gas is at least 300:1. In embodiments, the process gas includes hydrogen gas and optionally, ammonia gas.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method for selectively depositing a cobalt capping layer in accordance with some embodiments of the present disclosure.

FIGS. 2A-E depicts the stages of selectively depositing a cobalt capping layer in accordance with some embodiments of the present disclosure.

FIG. 3 depicts a process chamber suitable for performing a method of selectively depositing a cobalt capping layer in accordance with embodiments of the present disclosure.

FIG. 4 depicts another flow chart of a method for selectively depositing a cobalt capping layer in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods for selectively depositing a cobalt layer are provided herein. The methods advantageously provide the selective deposition of a cobalt capping layer onto a copper filled interconnect using a deposition process to avoid deposition of cobalt upon or damage to surrounding dielectric material having a low dielectric constant. The inventors have found that high amounts or concentrations of reducing agent such as hydrogen and/or ammonia in a process gas, compared to the amount of cobalt precursor flowed into a deposition chamber advantageously increases the selectivity of cobalt deposition to one or more copper surfaces over a dielectric surface. In embodiments, the selectivity is increased by an order of magnitude or more. In embodiments, the methods of the present disclosure may significantly dilute a cobalt precursor gas while maintaining or increasing the deposition rate of cobalt on a copper surface. Further, the methods of the present disclosure advantageously increase selectivity of cobalt to copper during deposition reducing and eliminating deposition on the dielectric surface and preventing leakages or shorts caused by cobalt deposited atop the adjacent dielectric material, while promoting the formation of thick cobalt capping layers and increased cobalt deposition rates and metallic coverage. The methods may be utilized in the formation of metal interconnects in an integrated circuit, or in the formation of a metal gate or a metal-contact gap fill process, as well as other suitable applications utilizing selectively deposited cobalt layers. In some embodiments, extensively increasing hydrogen gas flow to greater than 12,000 sccm dilutes the precursor on the dielectric surface while saturating a copper metal surface. Additional co-flow with ammonia gas performs a ligand exchange with cobalt precursor to clean dielectric surface and reduce defects.

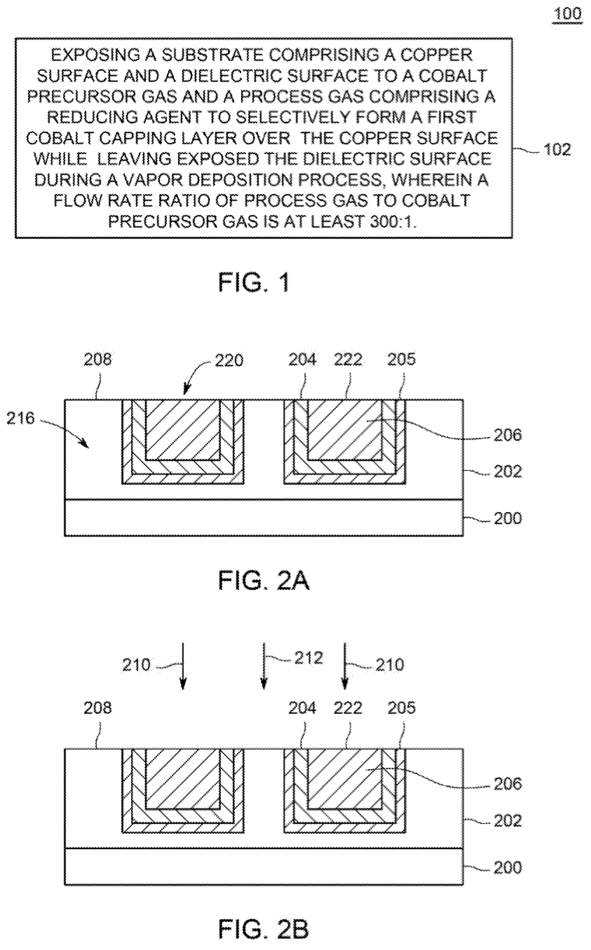

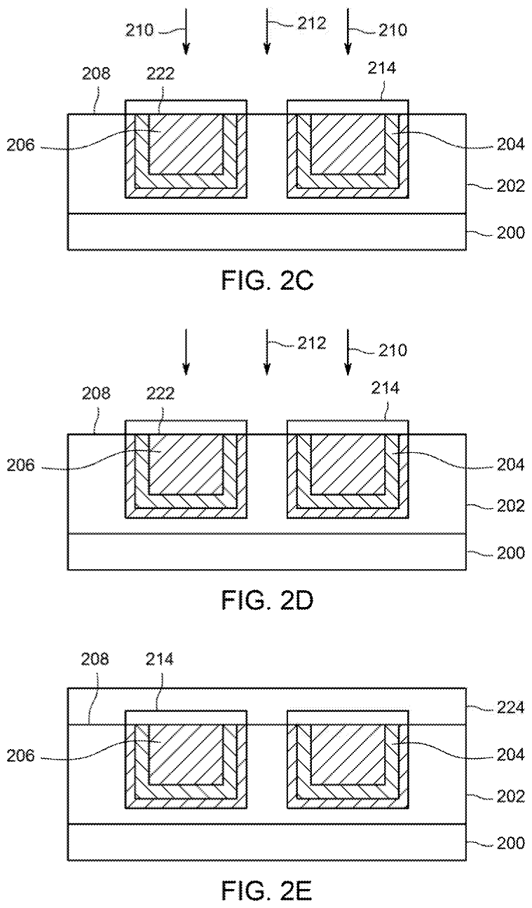

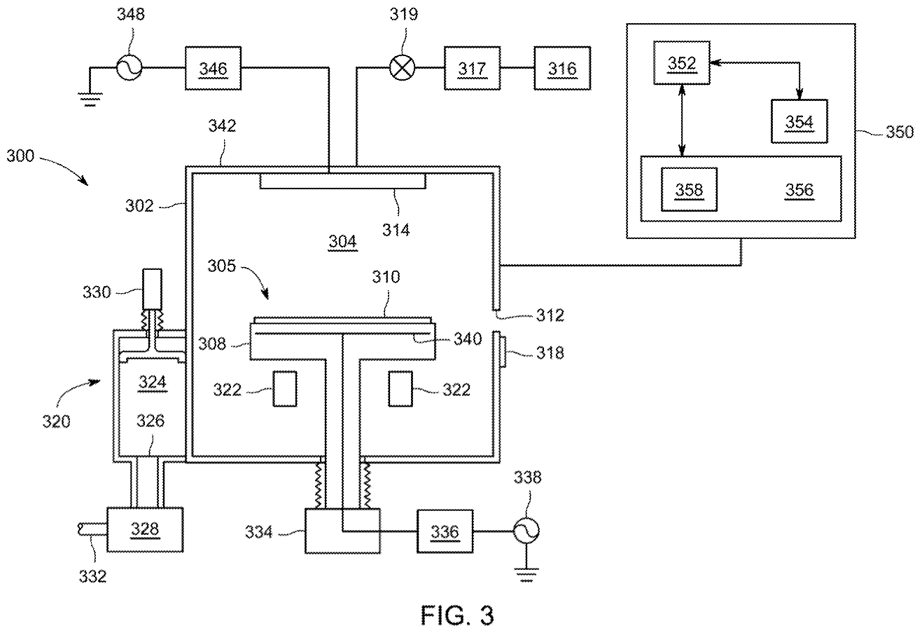

FIG. 1 depicts a flow chart of a method 100 for selectively depositing a cobalt capping layer in accordance with some embodiments of the present disclosure. The method 100 is described below with respect to the stages of selectively depositing a cobalt capping layer as depicted in FIGS. 2A-2E and may be performed, for example, in a suitable reactor, such as is described below with respect to FIG. 3.

In embodiments, the method 100 begins by providing a substrate 200 to a process chamber, such as is described below with respect to FIG. 3. The substrate 200 may be any suitable substrate having one or more feature(s) 216. For example, the substrate 200 may include one or more of silicon (Si), silicon oxide (SiO₂), or the like. In addition, the substrate 200 may include additional layers of materials or may have one or more completed or partially completed structures.

In some embodiments, as depicted, in FIG. 2A, the substrate 200 includes a dielectric layer 202 disposed on the substrate 200. In embodiments, the dielectric layer 202 includes a field such as dielectric surface 208 having one or more features 216 formed in the dielectric surface 208. In embodiments, the dielectric layer 202 contains a dielectric material, such as silicon oxide (SiO₂), silicon nitride (SiN), a low-k material, or the like. In some embodiments, the low-k material may be carbon-doped dielectric materials (such as carbon-doped silicon oxide (SiOC), BLACK DIAMOND® dielectric material available from Applied Materials, Inc. of Santa Clara, Calif., or the like), an organic polymer (such as polyimide, parylene, or the like), organic doped silicon glass (OSG), fluorine doped silicon glass (FSG), or the like. As used herein, low-k materials are materials having a dielectric constant of about 2.2 to about 3, and more specifically about 2.4 to about 2.8. In some embodiments, the one or more features 216 include an opening 220 formed in the dielectric surface 208 of the dielectric layer 202 and extending into the dielectric layer 202, away from the dielectric surface 208 and towards an opposing second surface of the dielectric layer 202. The opening 220 may be any suitable opening such as a via, trench, dual damascene structure, or the like. In embodiments, the opening 220 may be formed by etching the dielectric layer using any suitable etch process.

In some embodiments, a barrier layer 205 is deposited within the opening 220 using any suitable deposition process, for example, a physical vapor deposition process, a chemical vapor deposition process, or an atomic layer deposition process. In embodiments, the barrier layer 205 may serve as an electrical and/or physical barrier between the dielectric layer 202 and a metal-containing layer deposited or subsequently deposited in the opening, and/or may function as a better surface for attachment during the subsequent deposition of a metal-containing layer than a native surface of the substrate. In some embodiments, the barrier layer 205 may have any suitable thickness to function as a barrier layer, for example, within a range from about 5 angstroms to about 50 angstroms. In some embodiments, the barrier layer 205 may include a liner layer 204 disposed thereon including titanium, titanium nitride, tantalum, tantalum nitride, tungsten, tungsten nitride, derivatives thereof, or combinations thereof. In some embodiments, the liner layer 204 may contain a tantalum/tantalum nitride bilayer or titanium/titanium nitride bilayer.

In some embodiments, following the formation of the barrier layer 205, and optional liner layer 204, the opening 220 may be filled with a conductive (i.e. metal) material, such as copper. The copper layer 206 may be deposited using any suitable copper deposition process known in the art, for example a physical vapor deposition process, a chemical vapor deposition process, an electro-chemical plating process or the like. In some embodiments, a polishing process, such as a chemical mechanical polishing process may subsequently be performed to remove excess copper material and barrier layer material from the dielectric surface 208 of the dielectric layer 202.

In some embodiments, the polishing process may result in the formation of contaminants on the exposed copper surface 222 of the copper layer 206 and the dielectric surface 208 of the dielectric layer 202. For example, copper layer 206 contaminants usually contain copper oxides formed during or after the polishing process. The exposed copper surface 222 of the copper layer 206 may be oxidized by peroxides, water, or other reagents in the polishing solution or by oxygen within the ambient air. Contaminants may also include moisture, polishing solution remnants including surfactants and other additives, or particles of polished away materials. In embodiments, a pretreatment may be used to clean the exposed copper surface 222 of the copper layer 206 removing any copper oxide and/or metal or metal oxide deposited atop the dielectric surface 208 of the dielectric layer 202.

At 102 of method 100 includes exposing a substrate 200 including a copper surface such as exposed copper surface 222 and a dielectric surface 208 to a cobalt precursor gas 212 and a process gas 210 including a reducing agent as shown in FIG. 2B to selectively form a first cobalt capping layer 214 (FIG. 2C) over the copper surface such as exposed copper surface 222 while leaving exposed the dielectric surface 208 during a vapor deposition process, wherein a flow rate ratio of process gas 210 to cobalt precursor gas 212 is at least 300:1. In embodiments, the flow rate ratio of process gas 210 and cobalt precursor gas 212 is at least 400:1 such as 500;1, or 600:1, or a ratio between 400:1 to 600:1. In embodiments, the amount, concentration, or flow ratio of process gas 210 including a reducing agent such as hydrogen is higher than the precursor gas, in an amount sufficient to selectively deposit cobalt material atop the exposed copper surface 222, and not atop the dielectric surface 208. For example, in embodiments, process gas including a reducing agent such as hydrogen may be co-flowed into a process chamber at a flow rate of at least 8000 sccm, or at least 12,000 scccm along with cobalt precursor gas, e.g., comprising an inert gas such as argon and cobalt precursors flowed at a rate of 10 to 30 sccm. The inventors have observed that significant dilution of the precursor gas is suitable for maintaining or increasing the cobalt deposition rate with high selectivity. In some embodiments, the process gas may also include ammonia (NH3) to further enhance selectivity, for example, co-flowing ammonia gas at up to 1,000 sccm along with hydrogen gas and precursor gas as described herein.

In embodiments, a first cobalt capping layer 214 (FIG. 2C) may be selectively deposited or formed on a copper surface of the copper layer 206 while leaving bare the exposed surfaces of dielectric layer 202 such as dielectric surface 288 across the substrate field as shown in FIG. 2C. In embodiments, first cobalt capping layer 214 is selectively deposited on an exposed copper surface 222 of the copper layer 206 while leaving the exposed surfaces of dielectric layer 202 such as dielectric surface 208 free or at least substantially free of first cobalt capping layer 214. Initially, first cobalt capping layer 214 may be a continuous layer or discontinuous layer across exposed copper surface 222, but is a continuous layer after multiple deposition cycles.

At 102, and as depicted in FIG. 2B, the substrate 200 is exposed to a cobalt precursor gas 212. In embodiments, the cobalt precursor gas includes a cobalt precursor which has a general chemical formula (CO)ₓ.CO_{y}L_{z}, wherein: X is 1, 2, 3, 4, 5, 6, 7, 8, 9, 10, 11, or 12; Y is 1, 2, 3, 4, or 5; Z is 1, 2, 3, 4, 5, 6, 7, or 8; and L is a ligand independently selected from the group consisting of cyclopentadienyl, alkylcyclopentadienyl, methylcyclopentadienyl, pentamethylcyclopentadienyl, pentadienyl, alkylpentadienyl, cyclobutadienyl, butadienyl, allyl, ethylene, propylene, alkenes, dialkenes, alkynes, nitrosyl, ammonia, derivatives thereof, and combinations thereof. In some embodiments, the cobalt precursor gas includes a cobalt precursor selected from the group consisting of tricarbanyl allyl cobalt, cyclopentadienyl cobalt bis(carbonyl), methylcyclopentadienyl cobalt bis(carbonyl), ethylcyclopentadienyl cobalt bis(carbonyl), pentamethylcyclopentadienyl cobalt bis(carbonyl), dicobalt octa(carbonyl), nitrosyl cobalt tris(carbonyl), bis(cyclopentadienyl) cobalt, (cyclopentadienyl) cobalt (cyclohexadienyl), cyclopentadienyl cobalt (1,3-hexadienyl), (cyclobutadienyl) cobalt (cyclopentadienyl), bis(methylcyclopentadienyl) cobalt, (cyclopentadienyl) cobalt (5-methylcyclopentadienyl), bis(ethylene) cobalt (pentamethylcyclopentadienyl), derivatives thereof, complexes thereof, plasmas thereof, and combinations thereof. In some embodiments, the cobalt precursor comprises cyclopentadienyl cobalt bis(carbonyl). In some embodiments, the cobalt precursor gas is flowed into a process chamber process chamber at, a rate of about 10 to about 30 sccm.

In some embodiments, at 102, and as depicted in FIG. 2B, the substrate 200 is exposed to a process gas 210 including a reducing agent. For example, in some embodiments, the substrate 200 may be exposed to the process gas 210 including a reducing agent concurrent with exposing the substrate 200 to the cobalt precursor gas 212. In some embodiments, the process gas 210 includes a reducing agent such as hydrogen (e.g., H₂ or atomic-H), ammonia (NH₃), a hydrogen and ammonia mixture (H₂/NH₃), plasmas thereof, or combinations thereof. In some embodiments, the process gas includes a reducing agent is flowed into a process chamber at a rate of at least 8000 sccm, at least 12,000 sccm, or between 8000 sccm and 15,000 scccm. In some embodiments, the process gas further comprises ammonia (NH₃) gas at a flow rate of at least 500 sccm between 500 sccm and 1000 sccm, or below 1000 sccm. In some embodiments, the process gas includes hydrogen (H₂), ammonia (NH₃), and combinations thereof.

In some embodiments, the substrate 200 may be exposed to the process gas 210 including a reducing agent in a plasma process at a temperature of 200° C. to about 250° C. For example, the substrate 200 may be exposed to the reducing gas and heated to temperature of about 200 degrees Celsius to about 250 degrees Celsius for about 3 to 15 seconds.

In some embodiments, the substrate is exposed to the process gas 210 at an apparatus pressure of about 1 to about 100 Torr. In some embodiments, the process gas 210 further comprises hydrogen gas (H₂) and an inert gas, such as argon, helium, krypton or the like.

At 102, as depicted in FIG. 2C, a first cobalt capping layer 214 is selectively deposited atop the exposed copper surface 222 of the copper layer 206 while leaving the dielectric surface 208 of the dielectric layer 202 free or substantially free of cobalt formation. In embodiments, the first cobalt capping layer 214 is deposited by exposing the substrate 200 to a cobalt precursor gas 212. The first cobalt capping layer 214 is formed by the deposition of the cobalt precursor gas 212 in the process chamber 302 via a suitable deposition process, for example, a chemical vapor deposition process or atomic layer deposition process. In some embodiments, the cobalt precursor gas 212 may be provided to the process chamber 302 as described below along with a carrier gas, for example an inert gas, such as argon, helium, nitrogen or the like. In some embodiments, suitable reactant gases that may be provided to the process chamber 302 that are useful to forming cobalt material include hydrogen, ammonia, argon and combinations thereof.

In some embodiments, the ratio of the rate of cobalt deposition on the exposed copper surface 222 to the rate of cobalt deposition on the dielectric surface 208 is about 500:1 to about 900,000:1. In some embodiments, the thickness of the first cobalt capping layer 214 is about 5 angstroms to about 20 angstroms such as 15 angstroms. In some embodiments, an inert gas, for example, argon, helium, krypton, or the like, is supplied to the process chamber along with the cobalt precursor gas.

Optionally, as depicted in FIG. 2D, the substrate 200 may again be exposed to the process gas 210, as described above, to increase the dielectric constant of the low-k material of the dielectric layer 202 caused by prior processes discussed above or any additional processes performed after forming the first cobalt capping layer 214. Specifically, in embodiments, exposing the substrate 200 to the process gas 210 further improves (i.e. reduces) the dielectric constant of the dielectric layer 202 by about 1 percent to about 10 percent. In some embodiments, the substrate may again be exposed to the process gas 210 at the process conditions discussed above at 102 or at different process conditions. For example, in some embodiments, the substrate is again exposed to the process gas 210 for about 10 to about 300 seconds, for example about 60 to about 300 seconds.

Following selective deposition of the cobalt layer or, optionally, further exposure to the process gas 210, the method 100 generally ends and the substrate 200 may proceed for further processing. In some embodiments, subsequent processes such as deposition, etch, annealing, or the like may be performed to fabricate a finished device.

In some embodiments, as depicted in FIG. 2E, a dielectric barrier layer 224 of, for example, a low-k dielectric material as described above may be deposited over the first cobalt capping layer 214 and the dielectric surface 208 of the dielectric layer 202. In embodiments, dielectric barrier layer 224 includes a material suitable for a masking or etch-stop material. In embodiments, dielectric barrier layer 224 is a blocking layer.

In some embodiments, depending on the structure of the device formed, process sequence 102 may be repeated to deposit the cobalt layer to a predetermined thickness such as, for example, 10, 15, 20, 25 angstroms. In some embodiments, subsequent to process sequence 102, the substrate is contacted with ammonia plasma in an amount sufficient to remove impurities from the cobalt precursors. In embodiments, the ammonia plasma treatment prepares the first cobalt capping layer for deposition of a second cobalt capping layer directly thereon. A cycle of process sequence 102 and ammonia plasma processing may be performed to deposit the cobalt capping layer to a predetermined thickness such as 10 to 20 angstrom, or 15 angstrom.

FIG. 3 depicts a schematic diagram of an apparatus 300 of the kind that may be used to practice embodiments of the disclosure as discussed herein. The apparatus 300 may be any apparatus suitable for performing one or more substrate processes, for example but not limited to, deposition process such as chemical vapor deposition (CVD), atomic layer deposition (ALD), or the like. In some embodiments the process chamber 302 may be a standalone apparatus, as depicted below, or a the process chamber 302 may be part of a cluster tool, such as one of the CENTURA®, PRODUCER®, or ENDURA® cluster tools available from Applied Materials, Inc. of Santa Clara, Calif. For example, copper metal fill may be performed in one processing chamber and ammonia plasma processing for the removal of contaminants from first cobalt capping layer 214 on the exposed copper surface 222 of the copper layer 206 and the dielectric surface 208 of the dielectric layer 202, if any, may be performed in a different process chamber 302 coupled to the cluster tool. In some embodiments, copper deposition and cobalt deposition such as process sequence 102 may be performed in a single process chamber 302 coupled to a cluster tool.

The apparatus 300 may comprise a controller 350 and a process chamber 302 having an exhaust system 320 for removing excess process gases, processing by-products, cobalt precursor components, or the like, from the inner volume 305 of the process chamber 302. Exemplary process chambers may include any of several process chambers configured for chemical vapor deposition (CVD) or atomic layer deposition (ALD), available from Applied Materials, Inc. of Santa Clara, Calif. Other suitable process chambers from other manufacturers may similarly be used.

The process chamber 302 has an inner volume 305 that may include a processing volume 304. The processing volume 304 may be defined, for example, between a substrate support 308 disposed within the process chamber 302 for supporting a substrate 310 thereupon during processing and one or more gas inlets, such as a showerhead 314 and/or nozzles provided at predetermined locations. In some embodiments, the substrate support 308 may include a mechanism that retains or supports the substrate 310 on the surface of the substrate support 308, such as an electrostatic chuck, a vacuum chuck, a substrate retaining clamp, or the like (not shown). In some embodiments, the substrate support 308 may include mechanisms for controlling the substrate temperature (such as heating and/or cooling devices, not shown) and/or for controlling the species flux and/or ion energy proximate the substrate surface.

For example, in some embodiments, the substrate support 308 may include an RF bias electrode 340, The RF bias electrode 340 may be coupled to one or more RF bias power sources (one RF bias power source 338 shown) through one or more respective matching networks (matching network 336 shown). The one or more bias power sources may be capable of producing up to 1200 W or RF energy at a frequency of about 2 MHz to about 60 MHz, such as at about 2 MHz, or about 13.56 MHz, or about 60 Mhz. In some embodiments, two bias power sources may be provided for coupling RF power through respective matching networks to the RF bias electrode 340 at respective frequencies of about 2 MHz and about 13.56 MHz. The at least one bias power source may provide either continuous or pulsed power. In some embodiments, the bias power source alternatively may be a DC or pulsed DC source.

The substrate 316 may enter the process chamber 302 via an opening 312 in a wall of the process chamber 302. The opening 312 may be selectively sealed via a slit valve 318, or other mechanism for selectively providing access to the interior of the chamber through the opening 312. The substrate support 308 may be coupled to a lift mechanism 334 that may control the position of the substrate support 308 between a lower position (as shown) suitable for transferring substrates into and out of the chamber via the opening 312 and a selectable upper position suitable for processing. The process position may be selected to maximize process uniformity for a particular process. When in at least one of the elevated processing positions, the substrate support 308 may be disposed above the opening 312 to provide a symmetrical processing region.

The one or more gas inlets (e.g., the showerhead 314) may be coupled to a gas supply 316 for providing one or more process gases and/or cobalt precursor gasses through a mass flow controller 317 into the processing volume 304 of the process chamber 302. In addition, one or more valves 319 may be provided to control the flow of the one or more process gases. In embodiments, the process gas and precursor gas flow through separate lines to the process chamber to facilitate the high flow rate of process gas including a reducing agent such as hydrogen gas and/or ammonia gas, and a lower flow rate of precursor gas such as gas comprising cobalt precursors and an inert gas such as argon. In some embodiments, a mass flow controller 317 and one or more valves 319 may be used individually, or in conjunction to provide the process gases at predetermined flow rates at a constant flow rate, or pulsed (as described above).

Although a showerhead 314 is shown in FIG. 3, additional or alternative gas inlets may be provided such as nozzles or inlets disposed in the ceiling or on the sidewalls of the process chamber 302 or at other locations suitable for providing gases such as process gas and precursor gas to the process chamber 302, such as the base of the process chamber, the periphery of the substrate support, or the like.

The apparatus 300 may utilize capacitively coupled RF energy for plasma processing. For example, the process chamber 302 may have a ceiling 342 made from dielectric materials and a showerhead 314 that is at least partially conductive to provide an RF electrode (or a separate RF electrode may be provided). The showerhead 314 (or other RF electrode) may be coupled to one or more RF power sources (one RF power source 348 shown) through one or more respective matching networks (matching network 346 shown). The one or more plasma sources may be capable of producing up to about 3,000 W, or in some embodiments, up to about 5,000 W, of RF energy at a frequency of about 2 MHz and/or about 13.56 MHz or a high frequency, such as 27 MHz and/or 60 MHz. The exhaust system 320 generally includes a pumping plenum 324 and one or more conduits that couple the pumping plenum 324 to the inner volume 305 (and generally, the processing volume 304) of the process chamber 302.

A vacuum pump 328 may be coupled to the pumping plenum 324 via a pumping port 326 for pumping out the exhaust gases from the process chamber via one or more exhaust ports (two exhaust ports 322 shown). The vacuum pump 328 may be fluidly coupled to an exhaust outlet 332 for routing the exhaust to appropriate exhaust handling equipment. A valve 330 (such as a gate valve, or the like) may be disposed in the pumping plenum 324 to facilitate control of the flow rate of the exhaust gases in combination with the operation of the vacuum pump 328. Although a z-motion gate valve is shown, any suitable, process compatible valve for controlling the flow of the exhaust may be utilized.

To facilitate control of the process chamber 302 as described above, the controller 350 may be one of any form of general-purpose computer processor that can be used in an industrial setting for controlling various chambers and sub-processors. The memory, or computer-readable medium, 356 of the CPU 352 may be one or more of readily available memory such as random access memory (RAM), read only memory (ROM), floppy disk, hard disk, or any other form of digital storage, local or remote. The support circuits 354 are coupled to the CPU 352 for supporting the processor in a conventional manner. These circuits include cache, power supplies, clock circuits, input/output circuitry and subsystems, and the like.

The methods disclosed herein may generally be stored in the memory 356 as a software routine 358 that, when executed by the CPU 352, causes the process chamber 302 to perform processes of the present disclosure. The software routine 358 may also be stored and/or executed by a second CPU (not shown) that is remotely located from the hardware being controlled by the CPU 352. Some or all of the method of the present disclosure may also be performed in hardware. As such, the disclosure may be implemented in software and executed using a computer system, in hardware as, e.g., an application specific integrated circuit or other type of hardware implementation, or as a combination of software and hardware. The software routine 358 may be executed after the substrate 310 is positioned on the substrate support 308. The software routine 358, when executed by the CPU 352, transforms the general purpose computer into a specific purpose computer (controller) 350 that controls the chamber operation such that the methods disclosed herein are performed.

The disclosure may be practiced using other semiconductor substrate processing systems wherein the processing parameters may be adjusted to achieve acceptable characteristics by those skilled in the art by utilizing the teachings disclosed herein without departing from the spirit of the disclosure.

In some embodiments, the present disclosure relates to a process chamber configured for exposing a substrate including a copper surface and a dielectric surface to a cobalt precursor gas and a process gas including a reducing agent (such as hydrogen gas, ammonia gas, and combinations thereof) to selectively form a first cobalt capping layer over the copper surface while leaving exposed the dielectric surface during a vapor deposition process, wherein a flow rate ratio of process gas to cobalt precursor gas is at least 300:1, or between 300:1 and 600:1.

In some embodiments, the present disclosure relates to a non-transitory computer readable medium having instructions stored thereon that, when executed, cause a reaction chamber to perform a method of capping a copper surface on a substrate, including: exposing a substrate comprising, a copper surface and a dielectric surface to a cobalt precursor gas and a process gas including a reducing agent (such as hydrogen gas, ammonia gas, and combinations thereof) to selectively form a first cobalt capping layer over the copper surface while leaving exposed the dielectric surface during a vapor deposition process, wherein a flow rate ratio of process gas to cobalt precursor gas is at least 300:1.

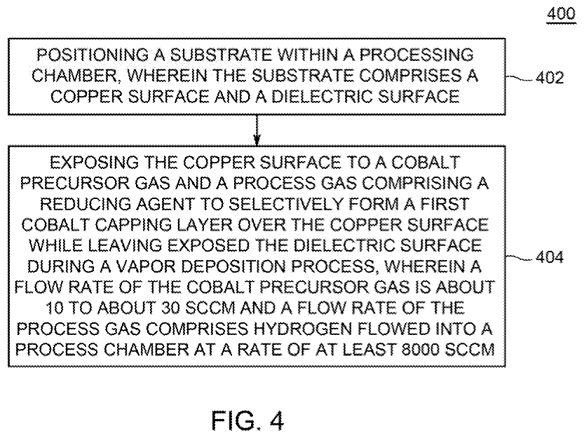

Referring now to FIG. 4, another flow chart of a method 400 for selectively depositing a cobalt layer and capping a copper surface on a substrate in accordance with some embodiments of the present disclosure is provided. At 402, the method includes positioning a substrate within a processing chamber, wherein the substrate includes a copper surface and a dielectric surface. In embodiments, at 404, the method includes exposing the copper surface to a cobalt precursor gas and a process gas comprising a reducing agent to selectively form a first cobalt capping layer over the copper surface while leaving exposed the dielectric surface during a vapor deposition process, wherein a flow rate of the cobalt precursor gas is about 10 to about 30 sccm and a flow rate of the process gas includes hydrogen flowed into a process chamber at a rate of at least 8000 sccm, at least 12000 sccm or more. In some embodiments, the process gas further comprises ammonia (NH₃) gas at a flow rate of at least 500 sccm, up to 1,000 scccm. In some embodiments, the first cobalt capping layer is contacted with ammonia plasma under conditions sufficient to remove impurities from the first cobalt capping layer. In embodiments, additional capping layers may be cyclically deposited using an ammonia plasma to deposit a plurality of cobalt layers to form a final cobalt capping layer at a predetermined thickness.

In some embodiments, the present disclosure relates to a method for capping a copper surface on a substrate, including: exposing a substrate including a copper surface and a dielectric surface to a cobalt precursor gas and a process gas including a reducing agent to selectively form a first cobalt capping layer over the copper surface while leaving exposed the dielectric surface during a vapor deposition process, wherein a flow rate ratio of process gas to cobalt precursor gas is at least 300:1. In some embodiments, the flow rate ratio of process gas to cobalt precursor gas is between 300:1 to 10,000:1. In some embodiments, the flow rate ratio of process gas to cobalt precursor gas is about 300:1, about 400:1, about 500:1, about 600:1, or about 700:1. In some embodiments, the process gas including a reducing agent is flowed into a process chamber at a rate of at least 8000 sccm. In some embodiments, the process gas further includes ammonia (NH₃) gas at a flow rate of at least 500 sccm. In some embodiments, the cobalt precursor gas is flowed into a process chamber process chamber at a rate of about 10 to about 30 sccm. In some embodiments, the process gas includes hydrogen (H₂), ammonia (NH₃), and combinations thereof. In some embodiments, cobalt precursor gas is flowed into a process chamber at a rate of about 10 to about 30 sccm, and wherein the process gas comprises hydrogen (H₂) flowed into a process chamber at a rate of at least 8000 sccm, and ammonia (NH3) flowed into a process chamber at a rate of at least 500 sccm. In some embodiments, the method further includes igniting a plasma such as an ammonia plasma after selectively forming the first cobalt capping layer, In some embodiments, exposing a substrate including a copper surface and a dielectric surface to a gaseous reducing agent and a cobalt precursor gas is performed for a time period within a range from about 3 seconds to about 15 seconds. In some embodiments, exposing a substrate including a copper surface and a dielectric surface to a gaseous reducing agent and a cobalt precursor gas is performed at a temperature of about 200° C. to about 250° C. In some embodiments, the methods further include exposing the first cobalt capping layer to a second cobalt precursor gas and a second process gas comprising a reducing agent to deposit a second cobalt capping layer atop the first cobalt capping layer. In some embodiments, a deposition cycle includes performing a vapor deposition process 2, 3, or more times to deposit a plurality of cobalt capping layers. In some embodiments, each of a plurality of cobalt capping layers is deposited to a thickness within a range from about 3 angstrom to about 5 angstrom. In some embodiments, the cobalt precursor gas includes a cobalt precursor which has a general chemical formula (CO)ₓCO_{y}L_{z}, wherein: X is 1, 2, 3, 4, 5, 6, 7, 8, 9, 10, 11, or 12; Y is 1, 2, 3, 4, or 5; Z is 1, 2, 3, 4, 5, 6, 7, or 8; and L is a ligand independently selected from the group consisting of cyclopentadienyl, alkylcyclopentadienyl, methylcyclopentadienyl, pentamethylcyclopentadienyl, pentadienyl, alkylpentadienyl, cyclobutadienyl, butadienyl, allyl, ethylene, propylene, alkenes, dialkenes, alkynes, nitrosyl, ammonia, derivatives thereof, and combinations thereof. In some embodiments, the cobalt precursor gas includes a cobalt precursor selected from the group consisting of tricarbonyl allyl cobalt, cyclopentadienyl cobalt bis(carbonyl), methylcyclopentadienyl cobalt bis(carbonyl), ethylcyclopentadienyl cobalt bis(carbonyl), pentamethylcyclopentadienyl cobalt bis(carbonyl), dicobalt octa(carbonyl), nitrosyl cobalt tris(carbonyl), bis(cyclopentadienyl) cobalt, (cyclopentadienyl) cobalt (cyclohexadienyl), cyclopentadienyl cobalt (1,3-hexadienyl), (cyclobutadienyl) cobalt (cyclopentadienyl), bis(methylcyclopentadienyl) cobalt, (cyclopentadienyl) cobalt (5-methylcyclopentadienyl), bis(ethylene) cobalt (pentamethylcyclopentadienyl), derivatives thereof, complexes thereof, plasmas thereof, and combinations thereof. In some embodiments, the cobalt precursor gas comprises or consists of cyclopentadienyl cobalt bis(carbonyl).

While the foregoing is directed to embodiments of the present disclosure, other and further embodiments of the disclosure may be devised without departing from the basic scope thereof.

1. A method for capping a copper surface on a substrate, comprising:
exposing a substrate comprising a copper surface and a dielectric surface to a cobalt precursor gas and a process gas comprising a reducing agent to selectively form a first cobalt capping layer over the copper surface while leaving exposed the dielectric surface during a vapor deposition process, wherein a flow rate ratio of process gas to cobalt precursor gas is at least 300:1.

2. The method of claim 1, wherein the process gas comprising a reducing agent is flowed into a process chamber at a rate of at least 8000 sccm.

3. The method of claim 1, wherein the process gas further comprises ammonia (NH₃) gas at a flow rate of at least 500 sccm.

4. The method of claim 1, wherein the cobalt precursor gas is flowed into a process chamber process chamber at a rate of about 10 to about 30 sccm.

5. The method of claim 1, wherein the process gas comprises hydrogen (H₂), ammonia (NH₃), and combinations thereof.

6. The method of claim 1, wherein cobalt precursor gas is flowed into a process chamber at a rate of about 10 to about 30 sccm, and wherein the process gas comprises hydrogen (H₂) flowed into the process chamber at a rate of at least 8000 sccm, and ammonia (NH₃) flowed into the process chamber at a rate of at least 500 sccm.

7. The method of claim 1, further comprising igniting an ammonia plasma after selectively forming the first cobalt capping layer.

8. The method of claim 1, wherein exposing a substrate comprising a copper surface and a dielectric surface to a gaseous reducing agent and a cobalt precursor gas is performed for a time period of about 3 seconds to about 15 seconds.

9. The method of claim 1, wherein exposing a substrate comprising a copper surface and a dielectric surface to a gaseous reducing agent and a cobalt precursor gas is performed at a temperature of about 200° C. to about 250° C.

10. The method of claim 1, further comprising exposing the first cobalt capping layer to a second cobalt precursor gas and a second process gas comprising a reducing agent to deposit a second cobalt capping layer atop the first cobalt capping layer.

11. The method of claim 10, wherein a deposition cycle comprises performing a vapor deposition process 2 or more times to deposit a plurality of cobalt capping layers.

12. The method of claim 10, wherein each of a plurality of cobalt capping layers is deposited to a thickness of about 3 angstroms to about 5 angstroms. 13, The method of claim 1, wherein the cobalt precursor gas comprises a cobalt precursor which has a general chemical formula (CO)ₓ.CO_{y}L_{z}, wherein:
X is 1, 2, 3, 4, 5, 6, 7, 8, 9, 10, 11, or 12;
Y is 1, 2, 3, 4, or 5;
Z is 1, 2, 3, 4, 5, 6, 7, or 8; and
L is a ligand independently selected from the group consisting of cyclopentadienyl, alkylcyclopentadienyl, methylcyclopentadienyl, pentamethylcyclopentadienyl, pentadienyl, alkylpentadienyl, cyclobutadienyl, butadienyl, allyl, ethylene, propylene, alkenes, dialkenes, alkynes, nitrosyl, ammonia, derivatives thereof, and combinations thereof.

14. The method of claim 1, wherein the cobalt precursor gas comprises a cobalt precursor selected from the group consisting of tricarbonyl allyl cobalt, cyclopentadienyl cobalt bis(carbonyl), methylcyclopentadienyl cobalt bis(carbonyl), ethylcyclopentadienyl cobalt bis(carbonyl), pentamethylcyclopentadienyl cobalt bis(carbonyl), dicobalt octa(carbonyl), nitrosyl cobalt tris(carbonyl), bis(cyclopentadienyl) cobalt, (cyclopentadienyl) cobalt (cyclohexadienyl), cyclopentadienyl cobalt (1,3-hexadienyl), (cyclobutadienyl) cobalt (cyclopentadienyl), bis(methylcyclopentadienyl) cobalt, (cyclopentadienyl) cobalt (5-methylcyclopentadienyl), bis(ethylene) cobalt (pentamethylcyclopentadienyl), derivatives thereof, complexes thereof, plasmas thereof, and combinations thereof.

15. The method of claim 1, wherein the cobalt precursor gas comprises cyclopentadienyl cobalt bis(carbonyl).

16. A method for capping a copper surface on a substrate, comprising:
positioning a substrate within a processing chamber, wherein the substrate comprises a copper surface and a dielectric surface; and
exposing the copper surface to a cobalt precursor gas and a process gas comprising a reducing agent to selectively form a first cobalt capping layer over the copper surface while leaving exposed the dielectric surface during a vapor deposition process, wherein a flow rate of the cobalt precursor gas is about 10 to about 30 sccm and a flow rate of the process gas includes hydrogen (H₂) flowed into a process chamber at a rate of at least 8000 sccm.

17. The method of claim 16, wherein the process gas further comprises ammonia (NH₃) gas at a flow rate of at least 500 sccm.

18. A non-transitory computer readable medium having instructions stored thereon that, when executed, cause a method of capping a copper surface on a substrate to be performed, the method comprising:
exposing a substrate comprising a copper surface and a dielectric surface to a cobalt precursor gas and a process gas comprising a reducing agent to selectively form a first cobalt capping layer over the copper surface while leaving exposed the dielectric surface during a vapor deposition process, wherein a flow rate ratio of process gas to cobalt precursor gas is at least 300:1.

19. The non-transitory computer readable medium of claim 18, wherein the method further comprises flowing the cobalt precursor gas into a process chamber at a rate of about 10 to about 30 sccm, and wherein the process gas comprises hydrogen (H₂) flowed into the process chamber at a rate of at least 8000 sccm.

20. The non-transitory computer readable medium of claim 18, wherein the process gas further comprises ammonia (NH₃) gas provided at a flow rate of at least 500 sccm.
